(19) United States
(12) Patent Application Publication
(10) Pub. No.: US 2025/0298071 A1
(43) Pub. Date: Sep. 25, 2025

(54) ELECTRICAL TESTING EQUIPMENT

(71) Applicant: Test Research, Inc., Taipei City (TW)

(72) Inventors: Yi TSAO, Taipei City (TW); Hsien Hung CHEN, Taipei City (TW); Yi-Hua PAN, Taipei City (TW)

(21) Appl. No.: 18/674,915

(22) Filed: May 26, 2024

(30) Foreign Application Priority Data
Mar. 19, 2024 (TW) 113202752

(51) Int. Cl. G01R 31/28

(52) U.S. Cl. CPC G01R 31/2834; G01R 31/2808

(57) ABSTRACT

An electrical testing equipment includes a main machine, a pair of conveyor rails and a first moving device. The conveyor rails are movably disposed on the main machine and configured to deliver a device under test. The first moving device is disposed on the main machine and connected with the conveyor rails. The first moving device is configured to move the conveyor rails close to or away from each other.

### RELATED APPLICATIONS

This application claims priority to Taiwan Application Serial Number 113202752, filed Mar. 19, 2024, which is herein incorporated by reference in its entirety.

### BACKGROUND

### Technical Field

The present disclosure relates to electrical testing equipment.

### Description of Related Art

As the demand for electronic devices has been increasing nowadays, the quality of various components of electronic devices becomes an important issue of the industry. Apart from improving the technology of manufacture of the components, the testing for the components has naturally also become an important part that cannot be ignored.

For example, electrical testing equipment is in general used to test the electrical behavior of electronic components in the industry. In the frequent processes of testing, the measures to improve the testing efficiency and decrease the testing cost are undoubtedly important issues which the industry highly concerns.

### SUMMARY

A technical aspect of the present disclosure is to provide an electrical testing equipment, which can be applied in an assembly line in order to improve the operational efficiency and reduce the operational cost.

According to an embodiment of the present disclosure, an electrical testing equipment includes a main machine, a pair of conveyor rails and a first moving device. The conveyor rails are movably disposed on the main machine and configured to deliver a device under test. The first moving device is disposed on the main machine and connected with the conveyor rails. The first moving device is configured to move the conveyor rails close to or away from each other.

In one or more embodiments of the present disclosure, the main machine has a supporting surface. The electrical testing equipment further includes a lower fixture. The lower fixture is disposed on the supporting surface. The lower fixture has a working surface. The working surface is configured to support the device under test. The working surface has a first height relative to the supporting surface. The conveyor rails have a second height relative to the supporting surface. The second height is larger than the first height.

In one or more embodiments of the present disclosure, when the conveyor rails move away from each other, the conveyor rails have a first distance therebetween. The electrical testing equipment further includes an upper fixture. The upper fixture is configured to move towards the lower fixture to sandwich with the lower fixture the device under test therebetween. The upper fixture has a width. The first distance is larger than the width.

In one or more embodiments of the present disclosure, when the conveyor rails move close to each other, the conveyor rails have a second distance therebetween. The second distance is less than the width.

In one or more embodiments of the present disclosure, the electrical testing equipment further includes a clamping device and a second moving device. The clamping device is configured to clamp the upper fixture. The second moving device is connected with the main machine and the clamping device. The second moving device is configured to move the clamping device relative to the main machine, such that the clamping device is moved close to or away from the lower fixture.

In one or more embodiments of the present disclosure, the upper fixture includes a fixture body and a plurality of first snapping portions. The first snapping portions are disposed on the fixture body. The clamping device includes a device body and a plurality of second snapping portions. The second snapping portions are movably connected with the device body and configured to snap with the first snapping portions.

In one or more embodiments of the present disclosure, the upper fixture and the lower fixture are respectively a vacuum fixture.

In one or more embodiments of the present disclosure, the electrical testing equipment further includes at least one supporting portion. The supporting portion is at least partially disposed inside the lower fixture. The supporting portion is configured to move relative to the lower fixture in order to at least partially protrude out of the working surface to support the device under test.

In one or more embodiments of the present disclosure, the conveyor rails are configured to deliver the test under device along a first direction. The first moving device is configured to move the conveyor rails close to or away from each other along a second direction. The second direction is perpendicular to the first direction.

In one or more embodiments of the present disclosure, the supporting portion is configured to move along a third direction relative to the lower fixture. The third direction is perpendicular to the first direction and the second direction.

In one or more embodiments of the present disclosure, the first moving device is further configured to move the conveyor rails close to or away from the lower fixture.

According to an embodiment of the present disclosure, an electrical testing equipment includes a main machine, a fixture module and a pair of conveyor rails. The fixture module includes a lower vacuum fixture and an upper vacuum fixture. The lower vacuum fixture is disposed on the main machine and configured to support a device under test. The upper vacuum fixture is movably connected with the main machine and defines a working space with the lower vacuum fixture therebetween. The conveyor rails are connected with the main machine and configured to move close to each other to get into the working space or away from each other to leave from the working space.

In one or more embodiments of the present disclosure, when the upper vacuum fixture is separated from the lower vacuum fixture, the conveyor rails are configured to be moved close to each other to get into the working space to support the device under test.

In one or more embodiments of the present disclosure, the electrical testing equipment further includes at least one supporting portion. The supporting portion is at least partially disposed inside the lower vacuum fixture. The supporting portion is configured to move relative to the lower vacuum fixture to at least partially protrude out of the lower vacuum fixture in order to lift up the device under test from the lower vacuum fixture.

In one or more embodiments of the present disclosure, the upper vacuum fixture is configured to move towards the lower vacuum fixture, such that the upper vacuum fixture and the lower vacuum fixture contact with opposite sides of the device under test.

The above-mentioned embodiments of the present disclosure have at least the following advantages: since the conveyor rails can be moved along the second direction and the third direction, and the supporting portion can move the device under test upwards or downwards relative to the lower fixture, under the condition that the upper fixture and the lower fixture are respectively a vacuum fixture, the electrical testing equipment can still be applied in an assembly line to receive the device under test from the previous working station and to deliver the device under test to the next working station after an electrical test is finished. In this way, the operational efficiency of the electrical testing equipment can be effectively improved, while the operational cost of the electrical testing equipment can be effectively reduced.

### BRIEF DESCRIPTION OF THE DRAWINGS

The disclosure can be more fully understood by reading the following detailed description of the embodiments, with reference made to the accompanying drawings as follows:

FIG. 1 is a front view of an electrical testing equipment according to an embodiment of the present disclosure;

FIG. 2 is a front view of the electrical testing equipment of FIG. 1, in which the conveyor rails are moved close to the lower fixture, and the supporting portion supports the device under test;

FIG. 3 is a front view of the electrical testing equipment of FIG. 2, in which the conveyor rails are moved away from each other;

FIG. 4 is a front view of the electrical testing equipment of FIG. 3, in which the upper fixture and the lower fixture sandwich the device under test therebetween, and the supporting portion is moved relative to the lower fixture such that the supporting portion is at least partially accommodated inside the lower fixture;

FIG. 5 is a front view of the electrical testing equipment of FIG. 4, in which the upper fixture is moved away from the lower fixture, and the supporting portion is moved relative to the lower fixture to lift up the device under test;

FIG. 6 is a front view of the electrical testing equipment of FIG. 5, in which the conveyor rails are moved close to each other to support the device under test;

FIG. 7 is a front view of the electrical testing equipment of FIG. 6, in which the conveyor rails are moved away from the lower fixture such that the device under test is detached from the supporting portion; and

FIG. 8 is a locally enlarged view of the upper fixture and the clamping device of FIG. 1.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

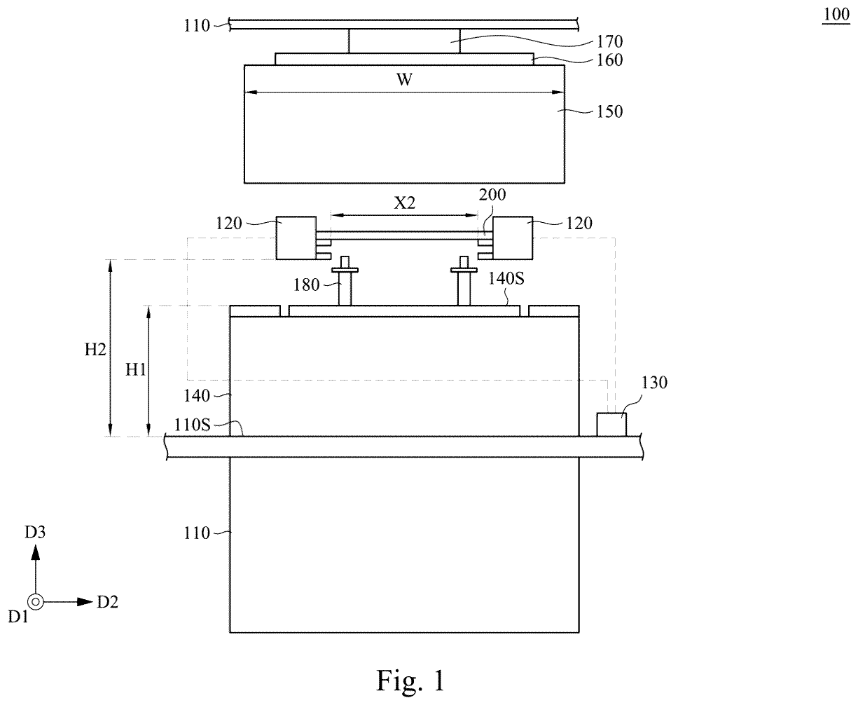

Reference is made to FIG. 1. FIG. 1 is a front view of an electrical testing equipment 100 according to an embodiment of the present disclosure. In this embodiment, as shown in FIG. 1, an electrical testing equipment 100 includes a main machine 110, a pair of conveyor rails 120 and a first moving device 130. The conveyor rails 120 are movably disposed on the main machine 110 and configured to deliver a device under test 200 along a first direction D1. For example, the conveyor rails 120 can receive the device under test 200 from the previous working station. The first moving device 130 is disposed on the main machine 110 and connected with the conveyor rails 120. The first moving device 130 is configured to move the conveyor rails 120 close to or away from each other along a second direction D2. The second direction D2 is perpendicular to the first direction D1. For the sake of drawing simplification, the connection between the first moving device 130 and the conveyor rails 120 is merely presented by hidden lines. When the conveyor rails 120 are moved close to each other along the second direction D2, as shown in FIG. 1, the conveyor rails 120 can support and deliver the device under test 200 along the first direction D1.

In this embodiment, as shown in FIG. 1, the electrical testing equipment 100 further includes an upper fixture 150 and a lower fixture 140. In practical applications, the upper fixture 150 and the lower fixture 140 are respectively a vacuum fixture. In addition, the main machine 110 has a supporting surface 110S. The lower fixture 140 is disposed on the supporting surface 110S of the main machine 110, while the upper fixture 150 is located at a side of the lower fixture 140 away from the main machine 110. The lower fixture 140 has a working surface 140S. The working surface 140S is configured to support the device under test 200. The working surface 140S is substantially parallel with the supporting surface 110S of the main machine 110. The working surface 140S of the lower fixture 140 has a first height H1 relative to the supporting surface 110S of the main machine 110, while the conveyor rails 120 have a second height H2 relative to the supporting surface 110S. In this embodiment, the second height H2 is larger than the first height H1. In other words, the conveyor rails 120 are located higher than the working surface 140S of the lower fixture 140.

Moreover, in this embodiment, as shown in FIG. 1, the electrical testing equipment 100 further includes a clamping device 160 and a second moving device 170. The clamping device 160 is configured to clamp the upper fixture 150. The second moving device 170 is connected with the main machine 110 and the clamping device 160. The second moving device 170 is configured to move the clamping device 160 relative to the main machine 110 along a third direction D3, such that the clamping device 160 is moved close to or away from the lower fixture 140. The third direction D3 is perpendicular to the first direction D1 and the second direction D2. The third direction D3 is substantially perpendicular to the supporting surface 110S of the main machine 110 and the working surface 140S of the lower fixture 140. To be more specific, the upper fixture 150 is configured to move towards the lower fixture 140 along the third direction D3 to sandwich with the lower fixture 140 the device under test 200 therebetween.

In practical applications, the upper fixture 150 has a width W along the second direction D2. When the conveyor rails 120 are moved close to each other along the second direction D2 to support and deliver the device under test 200 along the first direction D1, the conveyor rails 120 have a second distance X2 therebetween. The second distance X2 is less than the width W of the upper fixture 150. At this point, as shown in FIG. 1, the conveyor rails 120 are located between the upper fixture 150 and the lower fixture 140.

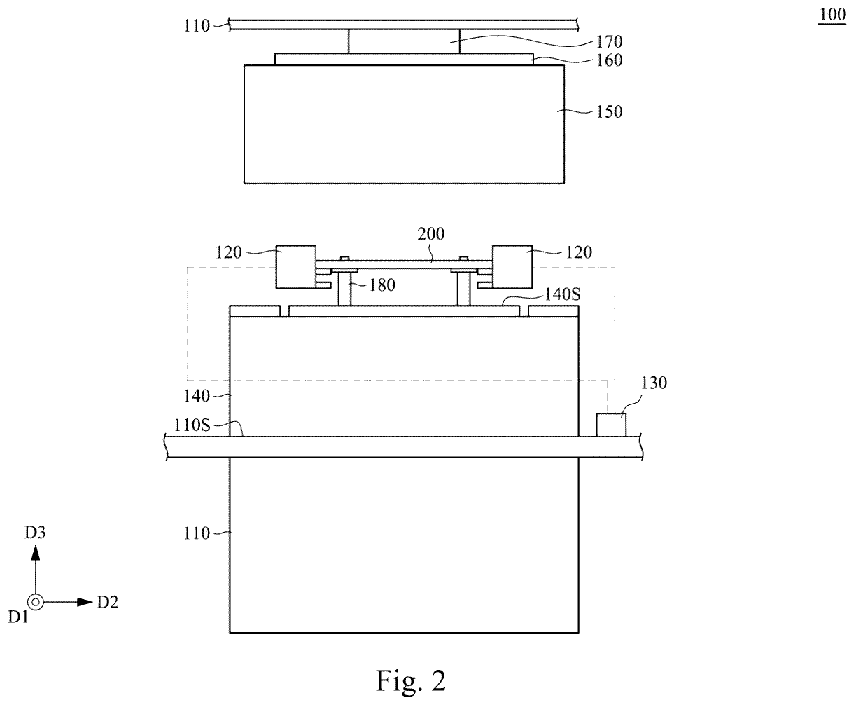

Reference is made to FIG. 2. FIG. 2 is a front view of the electrical testing equipment 100 of FIG. 1, in which the conveyor rails 120 are moved close to the lower fixture 140, and the supporting portion 180 supports the device under test 200. In this embodiment, the first moving device 130 is further configured to move the conveyor rails 120 close to or away from the lower fixture 140 along the third direction D3. As shown FIGS. 1-2, the electrical testing equipment 100 further includes at least one supporting portion 180. The supporting portion 180 is at least partially disposed inside the lower fixture 140. The supporting portion 180 is configured to move relative to the lower fixture 140 along the third direction D3 in order to at least partially protrude out of the working surface 140S. When the first moving device 130 moves the conveyor rails 120 close to the lower fixture 140 along the third direction D3, as shown in FIG. 2, the supporting portion 180 protruding out of the working surface 140S can contact and support the device under test 200.

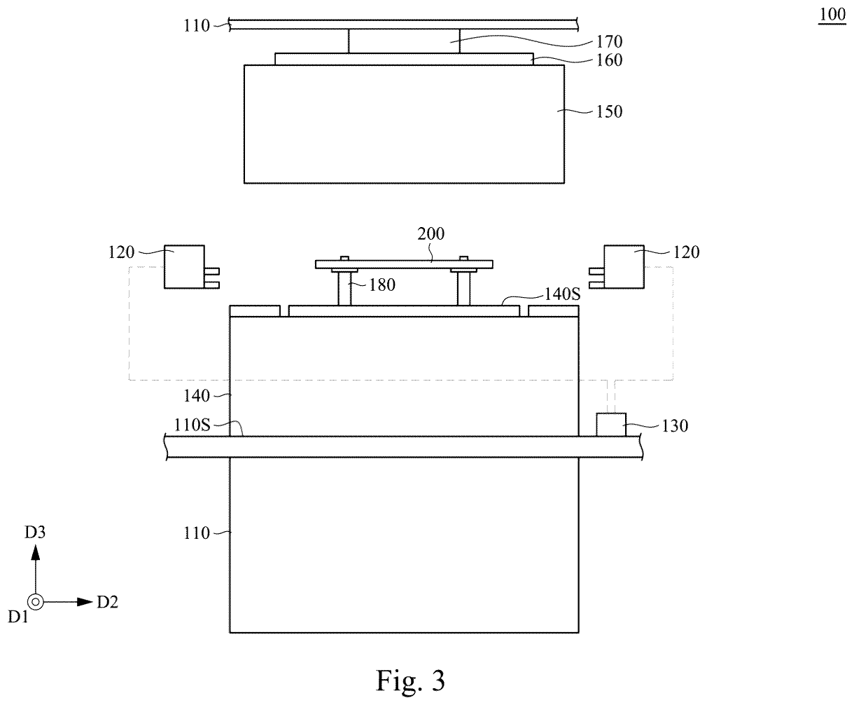

Reference is made to FIG. 3. FIG. 3 is a front view of the electrical testing equipment 100 of FIG. 2, in which the conveyor rails 120 are moved away from each other. In this embodiment, as shown in FIG. 3, when the supporting portion 180 protruding out of the working surface 140S supports the device under test 200, the conveyor rails 120 are moved away from each other along the second direction D2 to detach from the device under test 200.

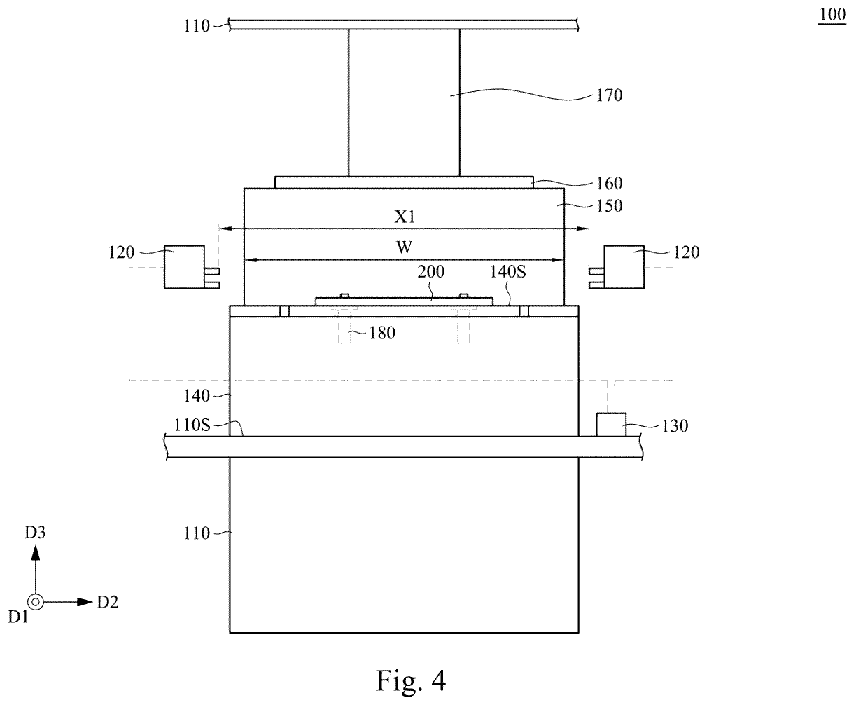

Reference is made to FIG. 4. FIG. 4 is a front view of the electrical testing equipment 100 of FIG. 3, in which the upper fixture 150 and the lower fixture 140 sandwich the device under test 200 therebetween, and the supporting portion 180 is moved relative to the lower fixture 140 such that the supporting portion 180 is at least partially accommodated inside the lower fixture 140. In this embodiment, as shown in FIG. 4, after the conveyor rails 120 are moved away from each other along the second direction D2, the conveyor rails 120 have a first distance X1 therebetween. In this embodiment, the first distance X1 is larger than the width W of the upper fixture 150. In other words, after the conveyor rails 120 are moved away from each other along the second direction D2, the upper fixture 150 can be moved towards the lower fixture 140, such that the device under test 200 is sandwiched between the upper fixture 150 and the lower fixture 140. At this point, the upper fixture 150 is at least partially located between the conveyor rails 120.

As mentioned above, the supporting portion 180 is configured to move relative to the lower fixture 140 along the third direction D3. Before the upper fixture 150 is moved towards the lower fixture 140 to sandwich the device under test 200 therebetween, as shown in FIG. 4, the supporting portion 180 is first moved at least partially into the lower fixture 140 along the third direction D3, such that the device under test 200 can be placed on the working surface 140S of the lower fixture 140 in a stable way. Thus, the device under test 200 can be properly sandwiched between the upper fixture 150 and the lower fixture 140, and subsequent electrical tests can be carried out to the device under test 200.

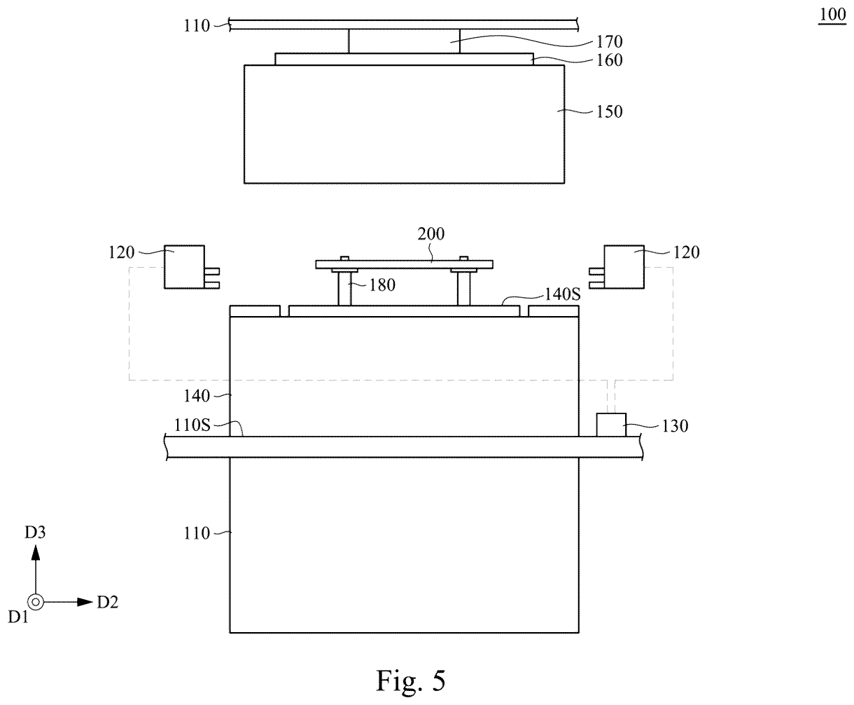

Reference is made to FIG. 5. FIG. 5 is a front view of the electrical testing equipment 100 of FIG. 4, in which the upper fixture 150 is moved away from the lower fixture 140, and the supporting portion 180 is moved relative to the lower fixture 140 to lift up the device under test 200. In this embodiment, as shown in FIG. 5, after an electrical test to the device under test 200 is finished, the upper fixture 150 is moved upwards to leave from the lower fixture 140 along the third direction D3. Afterwards, the supporting portion 180 is moved relative to the lower fixture 140 along the third direction D3 to lift up the device under test 200, such that the device under test 200 is moved away from the working surface 140S of the lower fixture 140. Moreover, the status of the electrical testing equipment 100 in FIG. 5 is substantially the same as the status in FIG. 3.

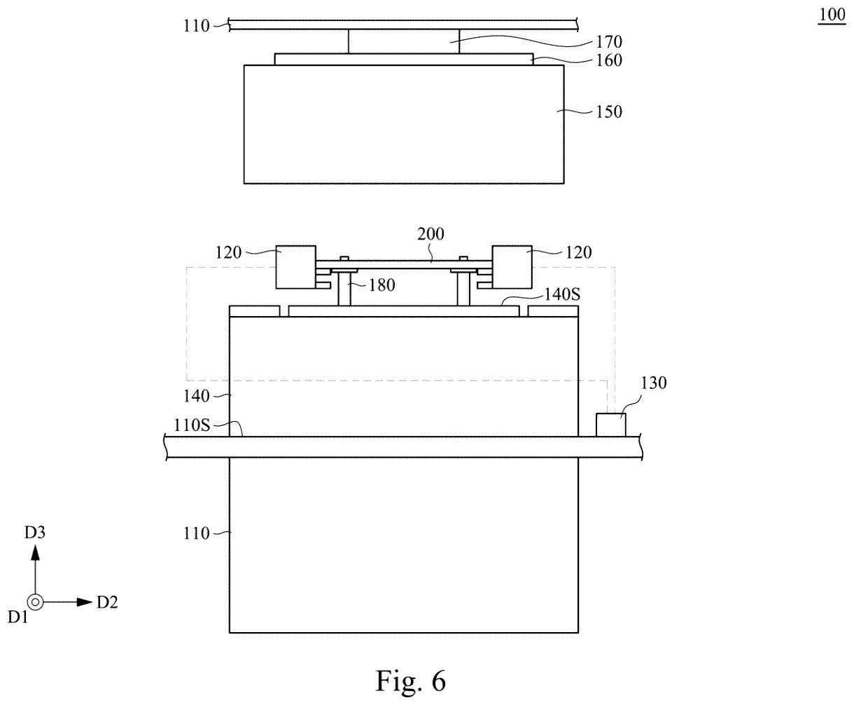

Reference is made to FIG. 6. FIG. 6 is a front view of the electrical testing equipment 100 of FIG. 5, in which the conveyor rails 120 are moved close to each other to support the device under test 200. In this embodiment, as shown in FIG. 6, after the upper fixture 150 is moved away from the lower fixture 140 and the supporting portion 180 is moved relative to the lower fixture 140 to lift up the device under test 200, the conveyor rails 120 are moved close to each other along the second direction D2 to support the device under test 200. Moreover, the status of the electrical testing equipment 100 in FIG. 6 is substantially the same as the status in FIG. 2.

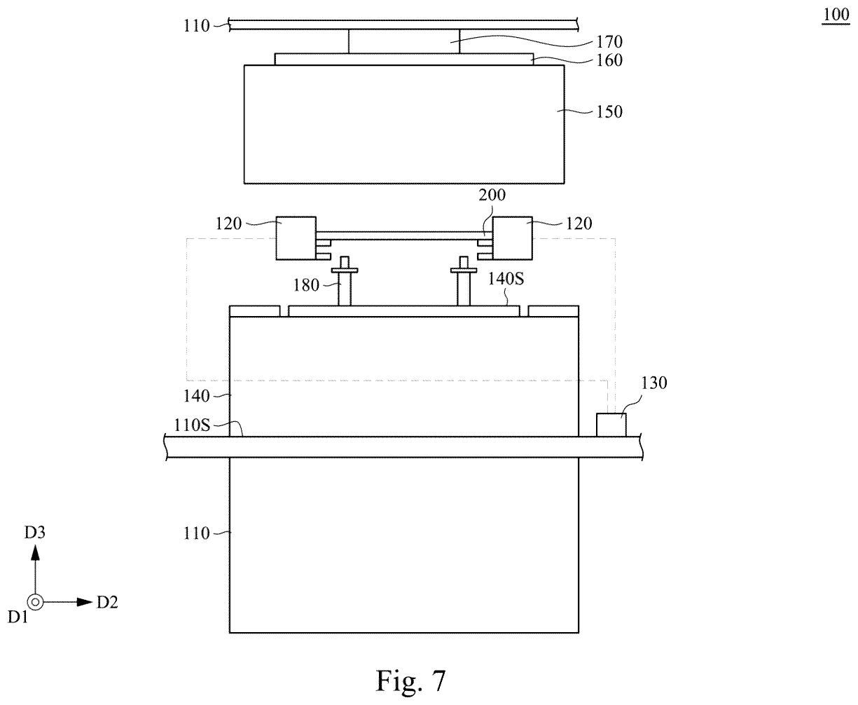

Reference is made to FIG. 7. FIG. 7 is a front view of the electrical testing equipment 100 of FIG. 6, in which the conveyor rails 120 are moved away from the lower fixture 140 such that the device under test 200 is detached from the supporting portion 180. In this embodiment, as shown in FIG. 7, after the conveyor rails 120 are moved close to each other along the second direction D2 to support the device under test 200, the first moving device 130 moves the conveyor rails 120 away from the lower fixture 140 along the third direction D3, such that the device under test 200 is detached from the supporting portion 180. At this point, the conveyor rails 120 can deliver the device under test 200 to the next working station. Moreover, the status of the electrical testing equipment 100 in FIG. 7 is substantially the same as the status in FIG. 1.

In simple words, since the conveyor rails 120 can be moved along the second direction D2 and the third direction D3, and the supporting portion 180 can move the device under test 200 upwards or downwards relative to the lower fixture 140, under the condition that the upper fixture 150 and the lower fixture 140 are respectively a vacuum fixture, the electrical testing equipment 100 can still be applied in an assembly line to receive the device under test 200 from the previous working station and to deliver the device under test 200 to the next working station after an electrical test is finished. In this way, the operational efficiency of the electrical testing equipment 100 can be effectively improved, while the operational cost of the electrical testing equipment 100 can be effectively reduced.

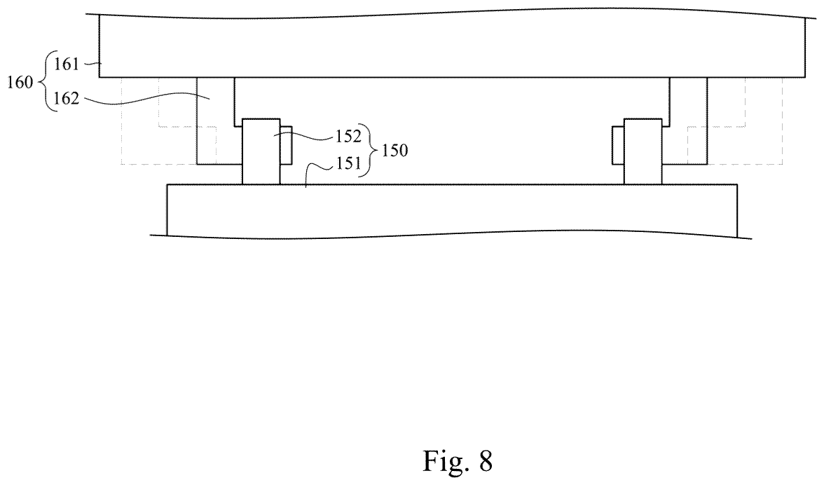

Reference is made to FIG. 8. FIG. 8 is a locally enlarged view of the upper fixture 150 and the clamping device 160 of FIG. 1. In this embodiment, as shown in FIG. 8, the upper fixture 150 includes a fixture body 151 and a plurality of first snapping portions 152. The first snapping portions 152 are disposed on the fixture body 151. The clamping device 160 includes a device body 161 and a plurality of second snapping portions 162. The second snapping portions 162 are movably connected with the device body 161 and configured to snap with the first snapping portions 152 of the upper fixture 150. To be specific, as shown in FIG. 8, the second snapping portions 162 presented by hidden lines are located in positions before moving and snapping with the first snapping portions 152, while the second snapping portions 162 presented by solid lines are already moved relative to the device body 161 and snapped with the first snapping portions 152 of the upper fixture 150. For the sake of drawing simplification, the first snapping portions 152 of the upper fixture 150 and the second snapping portions 162 of the clamping device 160 are not shown in other figures.

In conclusion, the aforementioned embodiments of the present disclosure have at least the following advantages: since the conveyor rails can be moved along the second direction and the third direction, and the supporting portion can move the device under test upwards or downwards relative to the lower fixture, under the condition that the upper fixture and the lower fixture are respectively a vacuum fixture, the electrical testing equipment can still be applied in an assembly line to receive the device under test from the previous working station and to deliver the device under test to the next working station after an electrical test is finished. In this way, the operational efficiency of the electrical testing equipment can be effectively improved, while the operational cost of the electrical testing equipment can be effectively reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. An electrical testing equipment, comprising:
a main machine;
a pair of conveyor rails movably disposed on the main machine and configured to deliver a device under test; and
a first moving device disposed on the main machine and connected with the conveyor rails, the first moving device being configured to move the conveyor rails close to or away from each other.

2. The electrical testing equipment of claim 1, wherein the main machine has a supporting surface, the electrical testing equipment further comprises:
a lower fixture disposed on the supporting surface, the lower fixture has a working surface, the working surface is configured to support the device under test, the working surface has a first height relative to the supporting surface, the conveyor rails have a second height relative to the supporting surface, the second height is larger than the first height.

3. The electrical testing equipment of claim 2, wherein when the conveyor rails move away from each other, the conveyor rails have a first distance therebetween, the electrical testing equipment further comprises:
an upper fixture configured to move towards the lower fixture to sandwich with the lower fixture the device under test therebetween, the upper fixture has a width, the first distance is larger than the width.

4. The electrical testing equipment of claim 3, wherein when the conveyor rails move close to each other, the conveyor rails have a second distance therebetween, the second distance is less than the width.

5. The electrical testing equipment of claim 3, further comprising:
a clamping device configured to clamp the upper fixture; and
a second moving device connected with the main machine and the clamping device, the second moving device being configured to move the clamping device relative to the main machine, such that the clamping device is moved close to or away from the lower fixture.

6. The electrical testing equipment of claim 5, wherein the upper fixture comprises a fixture body and a plurality of first snapping portions, the first snapping portions are disposed on the fixture body, the clamping device comprises a device body and a plurality of second snapping portions, the second snapping portions are movably connected with the device body and configured to snap with the first snapping portions.

7. The electrical testing equipment of claim 3, wherein the upper fixture and the lower fixture are respectively a vacuum fixture.

8. The electrical testing equipment of claim 2, further comprising:
at least one supporting portion at least partially disposed inside the lower fixture, the supporting portion being configured to move relative to the lower fixture in order to at least partially protrude out of the working surface to support the device under test.

9. The electrical testing equipment of claim 8, wherein the conveyor rails are configured to deliver the test under device along a first direction, the first moving device is configured to move the conveyor rails close to or away from each other along a second direction, the second direction is perpendicular to the first direction.

10. The electrical testing equipment of claim 9, wherein the supporting portion is configured to move along a third direction relative to the lower fixture, the third direction is perpendicular to the first direction and the second direction.

11. The electrical testing equipment of claim 8, wherein the first moving device is further configured to move the conveyor rails close to or away from the lower fixture.

12. An electrical testing equipment, comprising:
a main machine;
a fixture module, comprising:
a lower vacuum fixture disposed on the main machine and configured to support a device under test; and
an upper vacuum fixture movably connected with the main machine and defining a working space with the lower vacuum fixture therebetween; and
a pair of conveyor rails connected with the main machine and configured to move close to each other to get into the working space or away from each other to leave from the working space.

13. The electrical testing equipment of claim 12, wherein when the upper vacuum fixture is separated from the lower vacuum fixture, the conveyor rails are configured to be moved close to each other to get into the working space to support the device under test.

14. The electrical testing equipment of claim 12, further comprising:
at least one supporting portion at least partially disposed inside the lower vacuum fixture, the supporting portion being configured to move relative to the lower vacuum fixture to at least partially protrude out of the lower vacuum fixture in order to lift up the device under test from the lower vacuum fixture.

15. The electrical testing equipment of claim 12, wherein the upper vacuum fixture is configured to move towards the lower vacuum fixture, such that the upper vacuum fixture and the lower vacuum fixture contact with opposite sides of the device under test.
